(19) United States
(12) Patent Application Publication
(10) Pub. No.: US 2007/0051501 A1
(43) Pub. Date: Mar. 8, 2007

(54) HEAT DISSIPATION DEVICE

(76) Inventors: Yi-Qiang Wu, Shenzhen (CN); Liang-Hui Zhao, Shenzhen (CN)

Correspondence Address: NORTH AMERICA INTELLECTUAL PROPERTY CORPORATION, P.O. BOX 506, MERRIFIELD, VA, 22116, US

(21) Appl. No.: 11/308,472

(22) Filed: Mar. 28, 2006

(30) Foreign Application Priority Data
Sep. 2, 2005 (CN) 200510037028.3

(51) Int. Cl. H05K 7/20

(52) U.S. Cl. 165/104.33; 165/80.3; 361/700; 257/715

(57) ABSTRACT

A heat dissipation device includes a base (10), a first heat sink (20) disposed on the base (10), a second heat sink (30) attached on top of the first heat sink and a first heat pipe (40) connecting the base and the first heat sink and a pair of second heat pipes (50) connecting the base and the second heat sink.

### FIELD OF THE INVENTION

The present invention relates generally to a heat dissipation device, and more particularly to a heat dissipation device using heat pipes for enhancing heat removal from heat-generating components.

### DESCRIPTION OF RELATED ART

As computer technology continues to advance, electronic components such as central processing units (CPUs) of computers are being achieving faster operational speeds and greater functional capabilities. When a CPU operates at high speed in a computer enclosure, its temperature can increase greatly. It is thus desirable to dissipate the heat quickly, for example by using a heat dissipation device attached to the CPU in the enclosure. This allows the CPU and other electronic components in the enclosure to function within their normal operating temperature ranges, thereby assuring greater quality of data management, storage and transfer.

A conventional heat dissipation device comprises a base, a first heat sink disposed on the base, a second heat sink arranged on top of the first heat sink and at least one heat pipe thermally connecting the base with the first and second heat sinks. The first heat sink which is formed by extrusion, defines a groove in its bottom attached with the base. The second heat sink comprises a plurality of fins and a cover attached on a top surface of the fins. The cover defines a passage therein for accommodating at least one heat pipe. However, the heat pipe(s) only connect the bottom of the first heat sink and the cover of the second heat sink. Heat from heat-generating components is mainly transferred to two ends of the heat dissipation device. The heat can not be transferred to a middle of heat dissipation device and the top of the first heat sink and bottom of the second heat sink are not substantially utilized, which results in the heat not being distributed evenly over the whole heat dissipation device.

### SUMMARY OF INVENTION

A heat dissipation device in accordance with a preferred embodiment of the present invention comprises a base, a first heat sink disposed on the base, a second heat sink attached on top of the first heat sink and a first heat pipe connecting the base and the first heat sink and a pair of second heat pipes connecting the base and the second heat sink.

Other advantages and novel features will become more apparent from the following detailed description of preferred embodiments when taken in conjunction with the accompanying drawings, in which:

### BRIEF DESCRIPTION OF DRAWINGS

FIG. 1 is an isometric, exploded view of a heat dissipation device in accordance with a preferred embodiment of the present invention;

FIG. 2 is an assembled view of FIG. 1;

FIG. 3 is a side view of FIG. 2, showing the heat transference paths of the heat dissipation device; and

FIG. 4 is an isometric, exploded view of a heat dissipation device in accordance with another embodiment of the present invention.

### DETAILED DESCRIPTION

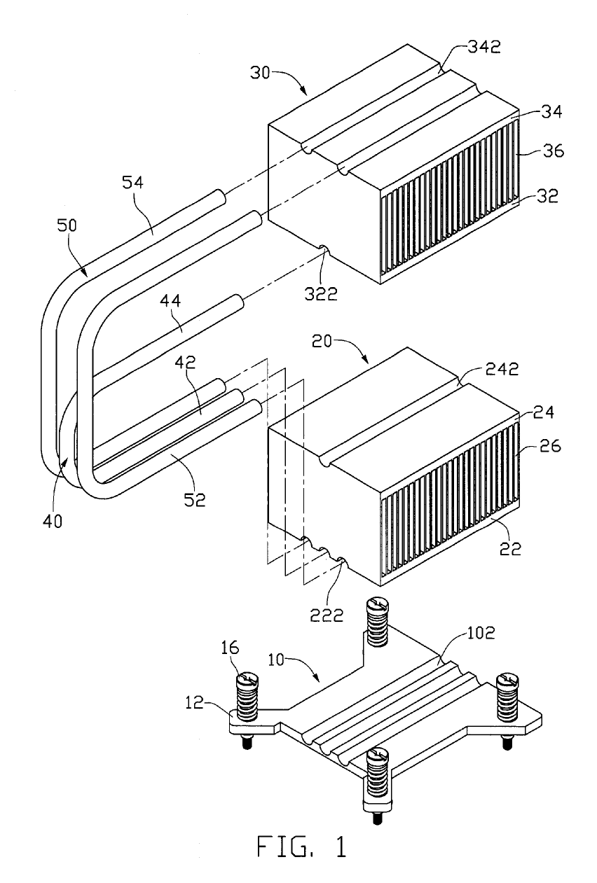

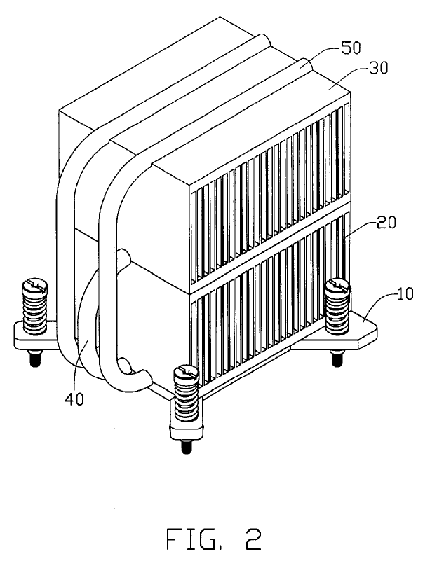

Referring to FIGS. 1-3, a heat dissipation device in accordance with a preferred embodiment of the present invention is disclosed comprising a base 10, a first heat sink 20 disposed on the base 10, a second heat sink 30 attached on top of the first heat sink 20 and a first heat pipe 40 connecting the base 10 and the first heat sink 20 and a pair of second heat pipes 50 connecting the base 10 and the second heat sink 30.

The base 10 is a rectangular plate and forms four fastening feet 12 extending outwardly from its four corners. Each fastening foot 12 defines a hole therein and a mounting component 16 is arranged in the hole. An upper surface of the base 10 defines three first grooves 102 therein.

The first heat sink 20 comprises first and second heat-transferring plates 22, 24 and a plurality of spaced first fins 26 sandwiched between the first and second heat-transferring plates 22, 24. A bottom surface of the first heat-transferring plate 22 is attached on the upper surface of the base 10.

The second heat sink 30 also comprises first and second heat-transferring boards 32, 34 and a plurality of spaced second fins 36 sandwiched between the first and second heat-transferring boards 32, 34. A bottom surface of the first heat-transferring board 32 is attached on a top surface of the second heat-transferring plate 24 of the first heat sink 20.

Three second grooves 222 corresponding to the first grooves 102 are defined in the first heat-transferring plate 22 of the first heat sink 20. A third groove 242 is defined in the second heat-transferring plate 24 of the first heat sink 20. A first slot 322 corresponding to the third groove 242 is defined in the first heat-transferring board 32 of the second heat sink 30. A pair of second slots 342 is defined in the second heat-transferring board 34 of the second heat sink 30. The first grooves 102 cooperate with the second grooves 222 to form first passages for accommodating both the first and second heat pipes 40, 50. The third groove 242 cooperates with the first slot 322 to form a second passage for accommodating the first heat pipe 40.

The first heat pipe 40 has a U-shaped configuration and comprises first and second parallel portions 42, 44. The first portion 42 functions as an evaporating portion of the heat pipe 40, while the second portion 44 functions as a condensing portion of the heat pipe 40. Each of the second heat pipes 50 also has a U-shaped configuration and comprises an evaporating portion 52 and a condensing portion 54. Distance between the first and second parallel portions 42, 44 of the first heat pipe 40 is smaller than that between the evaporating and condensing portions 52, 54 of the second heat pipe 50. The first parallel portion 42 and the evaporating portions 52 are accommodated in the first passages formed between the base 10 and the first heat-transferring plate 22 of the first heat sink 20. The second parallel portion 44 of the first heat pipe 40 is accommodated in the second passage formed between the second heat-transferring plate 24 of the first heat sink 20 and the first heat-transferring board 32 of the second heat sink 30. The condensing portions 54 of the second heat pipes 50 are arranged in the second slots 342 of the second heat-transferring board 34 of the second heat sink 30. The first and second heat pipes 40, 50, the base 10, and the first and second heat sinks 20, 30 are connected together by means of soldering.

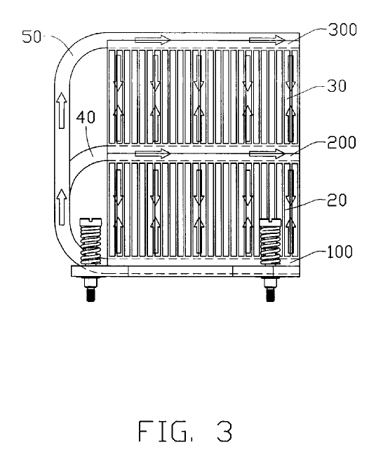

From above description of structure of the preferred embodiment of the present invention, three heat-spreading layers exist in the whole heat dissipation device. Referring to FIG. 3, a first heat-spreading layer 100 is formed between the base 10 and the first heat-transferring plate 22 of the first heat sink 20. A second heat-spreading layer 200 is formed between the second heat-transferring plate 24 of the first heat sink 20 and the first heat-transferring board 32 of the second heat sink 30. A third heat-spreading layer 300 is formed in the second heat-transferring board 34 of the second heat sink 30. The base 10 is thermally connected with the second and third heat-spreading layers 200, 300 respectively by the first and second heat pipes 40, 50. Heat transference paths of the heat dissipation device are shown in FIG. 3. The base 10 absorbs heat and part of this heat is directly transferred to the first fins 26 via the first heat-spreading layer 100. Another part of the heat is transferred to the second heat-spreading layer 200 via the second parallel portion 42 of the first heat pipe 40 and the heat is then quickly transferred upwardly to the second fins 36 and downwardly to the first fins 26. Still another part of the heat is transferred to the third heat-spreading layer 300 via the condensing portions 54 of the second heat pipes 50 and the heat is transferred downwardly to the second fins 36. As the arrows in FIG. 3 show, opposite top and bottom ends of each of the first and second fins 26, 36 evenly receive the heat from corresponding adjoining heat-spreading layers 100, 200 and 200, 300. The heat is evenly transferred through the whole of the heat dissipation device via the first and second heat pipes 40, 50. Every portion of the heat dissipation device can be substantially utilized and heat dissipation efficiency of the heat dissipation device is improved.

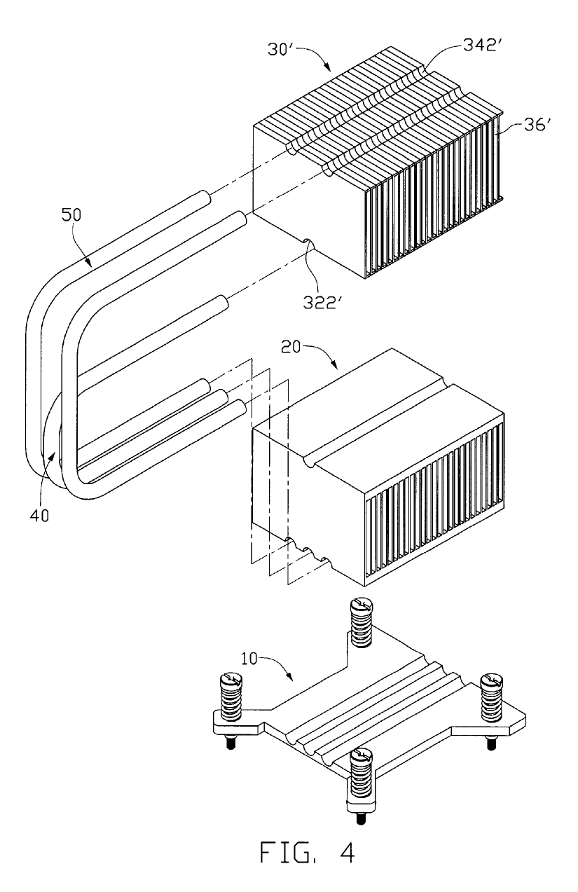

Referring to FIG. 4, a heat dissipation device is shown in accordance with another embodiment of the present invention. This second embodiment is substantially the same as the first embodiment, except that the second embodiment has a second heat sink 30′ which is different from the second heat sink 30 in the first embodiment. The second heat sink 30′ comprises a plurality of spaced heat dissipation fins 36′ and each heat dissipation fins 36′ comprises a pair of flanges extending perpendicularly from opposite top and bottom sides of the heat dissipation fins 36′. The flanges of the bottom side of the heat dissipation fins 36′ are attached with the second heat-transferring plate 24 of the second heat sink 20. A first slot 322′ and a pair of second slots 342′ are respectively defined in bottom and top portions of the second heat sink 30′. The first slot 322′ cooperates with the third groove 242 of the first heat sink 20 to form a channel accommodating the second parallel portion 44 of the first heat pipe 40. The condensing portions 54 of the second heat pipes 50 are accommodated in the second slots 342′ defined in the top portion of the second heat sink 30′.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A heat dissipation device comprising:
a base having a bottom face for contacting with a heat-generating electronic component and a top face;
a first heat sink disposed on the top face of the base, the first heat sink comprising first and second heat-transferring plates, a plurality of spaced first fins sandwiched between the first and second heat-transferring plates;
a second heat sink disposed on the first heat sink, comprising a plurality of spaced second fins;
a first heat pipe comprising first and second parallel-portions, the first portion being inserted in bottom of the first heat-transferring plate of the first heat sink and the second portion being sandwiched between the second heat-transferring plate of the first heat sink and a bottom portion of the second heat sink; and
a second heat pipe comprising evaporating and condensing portions, the evaporating portion being inserted in the bottom of the first heat-transferring plate of the first heat sink and the condensing portion being arranged in a top portion of the second heat sink;
wherein a first heat-spreading layer is formed between the base and the first heat-transferring plate of the first heat sink, a second heat-spreading layer is formed between the second heat-transferring plate of the first heat sink and the bottom portion of the second heat sink and a third heat-spreading layer is formed in the top portion of the second heat sink.

2. The heat dissipation device as claimed in claim 1, wherein the base defines a plurality of first grooves therein, the first portion of the first heat pipe and the evaporating portion of the second heat pipe being respectively arranged in the first grooves.

3. The heat dissipation device as claimed in claim 2, wherein a bottom surface of the first heat-transferring plate of the first heat sink contacts with a top surface of the base, and the bottom surface of the first heat-transferring plate defines a plurality of second grooves corresponding to the first grooves to form first passages for accommodating the first and second heat pipes.

4. The heat dissipation device as claimed in claim 3, wherein the second heat sink comprises first and second heat-transferring boards and the second fins are sandwiched between the first and second heat-transferring boards.

5. The heat dissipation device as claimed in claim 4, wherein the second heat-transferring plate of the first heat sink and the first heat-transferring board of the second heat sink respectively define a third groove and a first slot therein and the third groove cooperates with the first slot to form a second passage for accommodating the second parallel portion of the first heat pipe.

6. The heat dissipation device as claimed in claim 5, wherein the second heat-transferring board of the second heat sink defines a second slot in a top surface and the condensing portion of the second heat sink is arranged in the second slot.

7. The heat dissipation device as claimed in claim 1, wherein the first and second heat pipes are respectively U-shaped.

8. The heat dissipation device as claimed in claim 1, wherein the first heat sink is formed by extrusion.

9. The heat dissipation device as claimed in claim 2, wherein each of the second fins of the second heat sink comprises a pair of flanges extending perpendicularly from opposite top and bottom sides thereof, first and second slots being defined respectively in top and bottom portions of the second fins.

10. The heat dissipation device as claimed in claim 9, wherein the first slot of the second fins cooperates with the third groove of the second heat-transferring plate of the first heat sink to form a channel accommodating the second parallel portion of the first heat pipe.

11. The heat dissipation device as claimed in claim 10, wherein the condensing portion of the second heat pipe is arranged in the second slot.

12. A heat dissipation device comprising:
a base having a bottom face for contacting with a heat-generating electronic component and a top face;
a first heat sink mounted on the top face of the base;
a second heat sink mounted on a top of the first heat sink;
a first heat pipe having an evaporating portion inserted between the top face of the base and the first heat sink and a condensing portion inserted between the top of the first heat sink and the second heat sink; and
a second heat pipe having an evaporating portion inserted between the top face of the base and the first heat sink and a condensing portion inserted in a top of the second heat sink.
